(19) United States
(12) Patent Application Publication
(10) Pub. No.: US 2019/0025959 A1
(43) Pub. Date: Jan. 24, 2019

(54) CAPACITIVE TOUCH SENSOR

(71) Applicants: Mark V. KAPOOR, Houston, TX (US); David ENGLER, Houston, TX (US); Owen KIDD, Houston, TX (US); HEWLETT-PACKARD ENTERPRISE DEVELOPMENT LP, Houston, TX (US)

(72) Inventors: Mark V Kapoor, Houston, TX (US); David Engler, Cypress, TX (US); Owen Kidd, Houston, TX (US)

(21) Appl. No.: 16/065,396

(22) PCT Filed: Jan. 26, 2016
(86) PCT No.: PCT/US2016/014946

§ 371 Date: Jun. 22, 2018

(51) Int. Cl. G06F 3/044; H03K 17/955

(52) U.S. Cl. CPC G06F 3/044; H03K 17/962; H03K 17/955

(57) ABSTRACT

A capacitive touch sensor detects proximity of touch presence. The capacitive touch sensor includes a conductive surface at an edge of a substrate thereof.

### BACKGROUND

Electronic devices, including computing devices like computers, typically have one or more buttons, including, for instance, an on/off button. Buttons traditionally have been implemented as mechanically actuated switches. More recently, buttons have been implemented as capacitive touch sensors.

### BRIEF DESCRIPTION OF THE DRAWINGS

FIG. 1 is a diagram of an example capacitive touch sensor having a conductive surface at a substrate edge.

FIG. 2 is a diagram of another example capacitive touch sensor, consistent with but more detailed than that of FIG. 1, having a conductive surface at a substrate edge.

FIGS. 3A, 3B, 3C, and 3D are diagrams of different example conductive surfaces at a substrate edge that can be employed within a capacitive touch sensor.

FIG. 4 is a flowchart of an example method for detecting touch presence proximity using a capacitive touch sensor having a conductive surface at a substrate edge.

FIG. 5 is a flowchart of another example method, consistent with but more detailed than that of FIG. 4, for detecting touch presence proximity using a capacitive touch sensor having a conductive surface at a substrate edge.

FIG. 6 is a diagram of an example device including a capacitive touch sensor having a conductive surface at a substrate edge.

### DETAILED DESCRIPTION

As noted in the background section, buttons of electronic devices can be implemented as capacitive touch sensors. A capacitive touch sensor includes a ground layer and a conductive surface separated by a dielectric to form a capacitor. Touching, or proximately touching, the conductive surface changes the capacitance of this capacitor, and thus permits user actuation of the button.

Traditionally, the conductive surface, or sensor pad, of a capacitive touch sensor has been formed on the top (or bottom) surface of a substrate, such as a logic board or printed circuit board. However, such capacitive touch sensors are costly to integrate with certain types of electronic devices, such as rack-mounted devices like server computers, or servers. For instance, a rack-mounted device includes an outwardly facing housing surface against which the edge of the primary logic board thereof abuts. To employ an existing capacitive touch sensor within this surface, the device has to have a secondary logic board having its top (or bottom) surface with the touch pad positioned against the outwardly facing housing surface.

Disclosed herein are techniques to overcome this problem with existing capacitive touch sensors. In particular, the conductive surface, or touch pad, is innovatively located at the edge of the substrate of a capacitive touch sensor, such as a logic board or printed circuit board. Therefore, in the context of electronic devices like rack-mounted devices, the capacitive touch sensor can be integrated within the primary logic board of such an electronic board, obviating usage of a secondary logic board.

Such a novel capacitive touch sensor can realize immense cost savings. At the time of filing the present patent application, for instance, using a mechanically actuated button within a rack-mounted server may cost about $0.95, whereas using an existing capacitive touch sensor-implemented button may cost about $0.90. By not having to employ a secondary logic board, using a capacitive touch sensor in accordance with the non-obvious techniques disclosed herein may cost as little as $0.30, which is a 68% cost savings compared to a mechanically actuated button and a 67% cost savings compared to an existing capacitive touch-sensor implemented button.

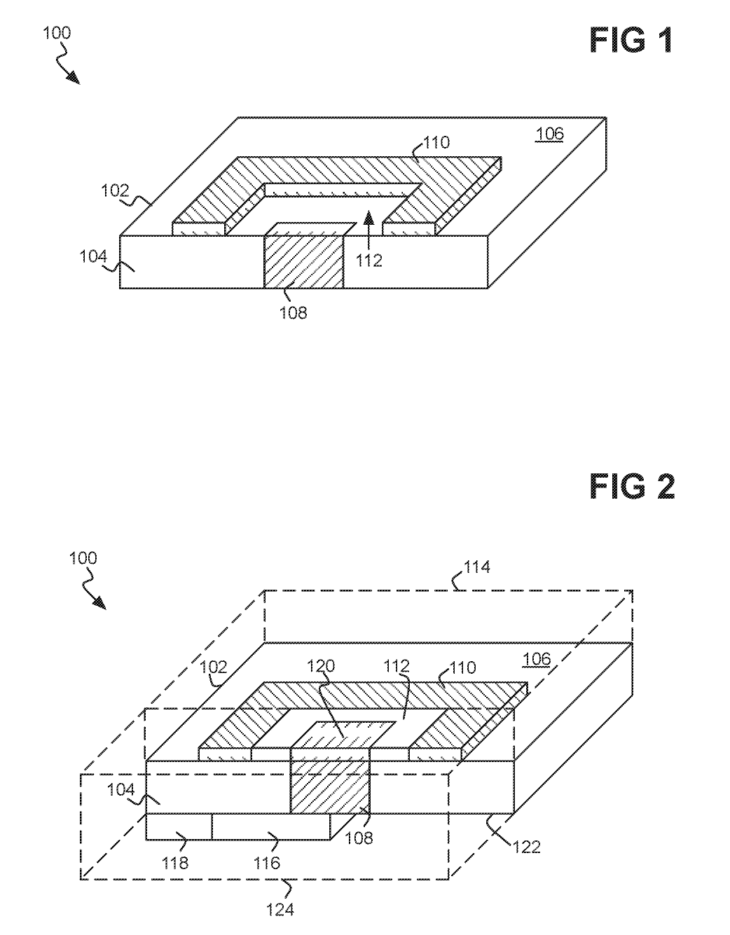

FIG. 1 shows an example capacitive touch sensor 100. The sensor 100 includes a substrate 102 having an edge 104 and a broad side 106. The substrate 102 may be a printed circuit board (PCB), which is also referred to as a logic board. A conductive surface 108 is disposed at the edge 104 of the substrate 102. A ground layer 110 is disposed at the substrate 102, specifically on the broad side 106 thereof. A dielectric 112 is disposed between the conductive surface 108 and the ground layer 110. The dielectric 112 in the example of FIG. 1 is a void, but in another implementation may be an insulative material.

The conductive surface 108, the ground layer 110, and the dielectric 112 form a capacitor, with the conductive surface 108 and the ground layer 110 being the plates of the capacitor and the dielectric 112 being the dielectric of the capacitor. The capacitance of this capacitor changes responsive to proximity of touch presence at the conductive surface 108. For example, when a user moves a finger proximate to or touches the conductive surface 108—which is referred to as touch presence proximity—the capacitance of the capacitor changes.

FIG. 2 shows another example capacitive touch sensor 100. The sensor 100 of FIG. 2 also includes the substrate 102 having the edge 104 and the broad side 106. The substrate 102 also has a broad side 122 opposite the broad side 106. The conductive surface 108 is again disposed at the edge 104 of the substrate 102. The ground layer 110 is again disposed on the broad side 106 of the substrate 102. The dielectric 112 is again disposed between the conductive surface 108 and the ground layer 110.

The capacitive touch sensor 100 also includes a conductive surface 120 disposed on the broad side 106 of the substrate 102. The conductive surface 120 is conductively connected to the conductive surface 108. The conductive surfaces 108 and 120 may be integrated with one another, in that they are fabricated at the same time and are of the same material. The conductive surfaces 108 and 120 may also be separate from one another, in that they are fabricated at different times and/or are of different materials.

The dielectric 112 is an insulative material in FIG. 2, and is specifically disposed between the conductive surfaces 108 and 120, and the ground layer 110. An overlay 114 on the broad side 106 of the substrate 102, outlined with dotted lines and shown as transparent in FIG. 2 for illustrative clarity, extends over the ground layer 110, the dielectric 112, and the conductive surface 120. A conductive trace 116 disposed on the broad side 122 is conductively connected to the conductive surface 108 at the edge 104 of the substrate 102. An input/output (I/O) pin 118 disposed on the broad side 122 is conductively connected to the conductive trace 116. Another overlay 124, and also outlined with dotted lines and shown as transparent in FIG. 2 for illustrative clarity, extends over the edge 104 of the substrate 102, and thus over the conductive surface 108. The overlays 114 and 124 may be integrated with one another, in that they are formed at the same time and of the same material, or may be separate from one another, in that they are formed at different times and/or of different materials.

Electronic circuitry can thus be connected to the I/O pin 118 to measure the capacitance of the capacitor formed by the conductive surfaces 108 and 120, the ground layer 110, and the dielectric 112. In the example of FIG. 2, the conductive surfaces 108 and 120 form one plate of the capacitor, and the ground layer 110 forms the other plate, with the dielectric 112 serving as the dielectric of the capacitor. The capacitance of this capacitor changes responsive to proximity of touch presence at the conductive surface 108, and the changing capacitance is measurable at the I/O pin 118.

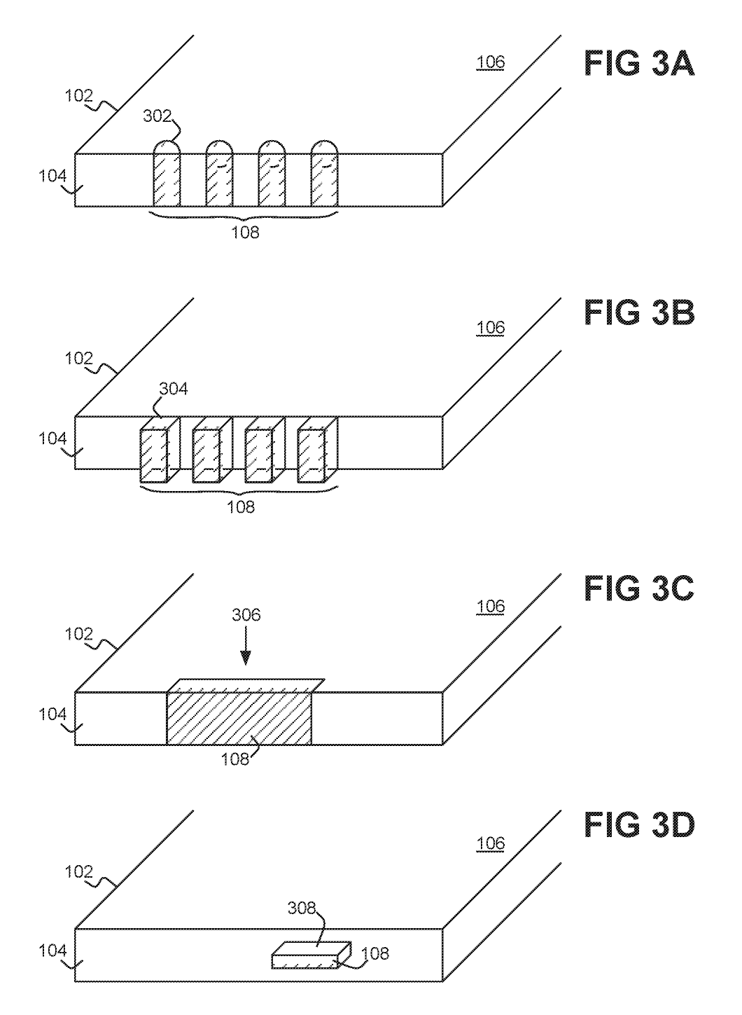

FIGS. 3A, 3B, 3C, and 3D show different examples of the conductive surface 108 at the edge 104 of the substrate 102 having the broad side 106. In FIG. 3A, the conductive surface 108 is formed as a number of vias 302 at the edge 104 that are plated or filled with a conductive material. The conductive vias 302 can be conductively connected to one another via another conductive surface, such as the conductive surface 120 of FIG. 2, and/or via a conductive trace, such as the trace 116 of FIG. 2. In FIG. 3B, the conductive surface 108 is formed as a number of castellations 304 of a conductive material at the edge 104. The conductive castellations 304 can be conductively connected to one another via another conductive surface, such as the conductive surface 120 of FIG. 2, which may at least partially extend over the castellations, and/or via a conductive trace, such as the trace 116 of FIG. 2.

In FIG. 3C, the conductive surface 108 is formed as a via or slot 306 at the edge 104 of the substrate 102 that is plated or filled with a conductive material. The via or slot 308 has a long dimension parallel to the long dimension of the edge 104. In FIG. 3D, the conductive surface 108 is formed as an electrical component 308 at the edge 104 that is plated with a conductive material at least on the surface thereof parallel the surface of the edge 104. The electrical component 308 may be a discrete resistor or other electrical component, and may be used on the substrate 102 for other functionality, owing to its electrical function, in addition to being plated to serve as part of the capacitive touch sensor 100. The plated surface of the electrical component 308 may be conductively connected to the trace 116 of FIG. 2 via another electrical trace specifically disposed on the edge 104 between the component 308 and the trace 116.

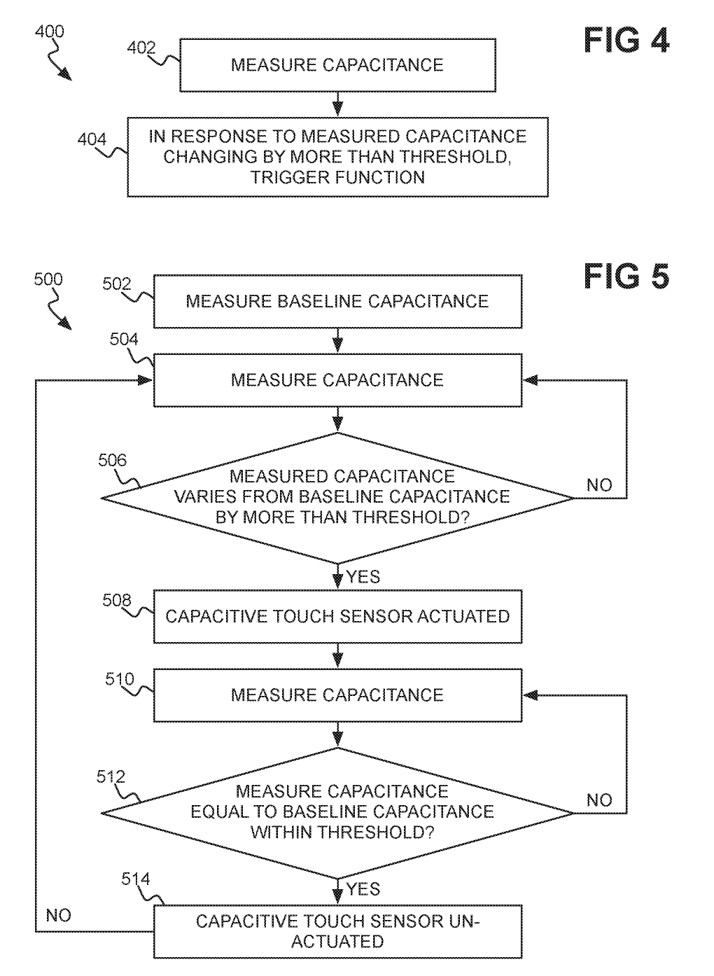

FIG. 4 shows an example method 400 for detecting touch presence capacity using the capacitive touch sensor 100. The capacitance of the capacitor formed by at least the conductive surface 108, the ground layer 110, and the dielectric 112 is measured (402). For example, a measuring circuit may be conductively connected to the I/O pin 118 of FIG. 2 to measure the capacitance. If the measured capacitance changes by more than a threshold, then a function corresponding to actuation of the capacitive touch sensor 100 is triggered (404). For example, the function may be to completely turn on an electronic device of which the sensor 100 is a part if the device is currently off, or at least partially turn off the device if the device is currently on.

FIG. 5 shows another example 500 for detecting touch presence capacity using the capacitive touch sensor 100. A baseline capacitance of the capacitor formed by at least the conductive surface 108, the ground layer 110, and the dielectric 112 is measured or specified (504). For example, this baseline capacitance may be measured at the time of fabrication of the capacitive touch sensor 100, or at a time when it is known that there is no touch presence proximity at the sensor 100. The capacitance may be measured a number of times and the mean taken to establish the baseline capacitance.

Then, when the capacitive touch sensor 100 is part of an electronic device to trigger a function associated with the device, the capacitance is continuously or at least periodically measured (504). If the measured capacitance varies from the baseline capacitance by more than a threshold (506), then touch presence proximity at the sensor 100 has been detected such that it is said that the sensor 100 has been actuated (508). As a result of such actuation, a function corresponding to the action may be performed per part 404 of the method 400. Otherwise, if the measured capacitance does not vary from the baseline capacitance by more than the threshold (506), the capacitance remains being measured as before (504).

After the actuation of the capacitive touch sensor 100, the capacitance may again be continuously or at least periodically measured (510). If the measured capacitance is equal to the baseline capacitance within a threshold (512), then touch presence proximity at the sensor 100 is no longer being detected such that it is said that the sensor 100 is no longer actuated (514). Otherwise, if the measured capacitance is not equal to the baseline capacitance within the threshold (512), the capacitance remains being measured as before (510). After the un-actuation of the sensor 100, the method 500 can be repeated at part 504.

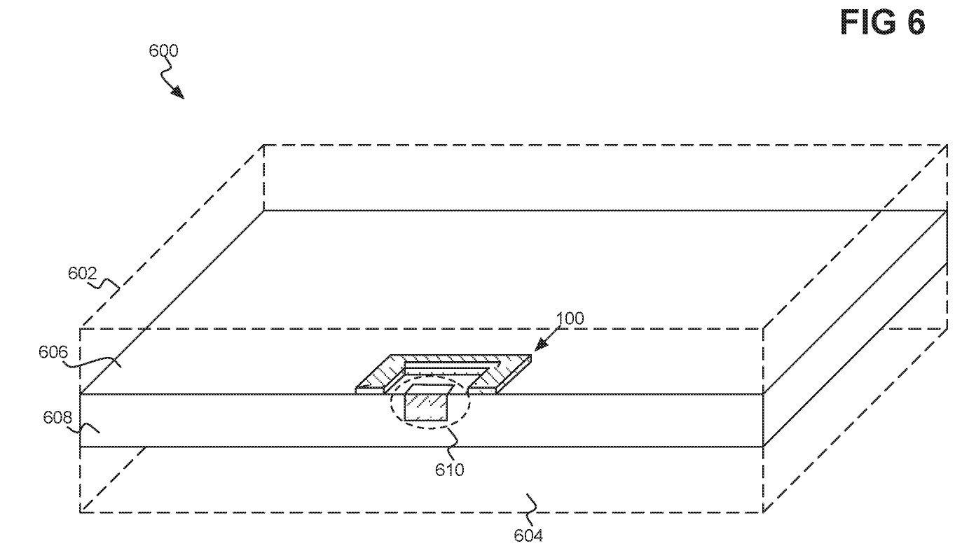

FIG. 6 shows an example device 600. The device 600 may be an electronic device, such as a computing device like a server. The device 600 may be a rack-mountable device, having a width of seventeen inches, and a height measured in one or more than one “U,” where a “U” is equal to 1.75 inches. The device 600 includes a housing 602 having an outwardly facing surface 604. For example, if the device 600 were mounted in a rack, the surface 604 would be the surface that faces outward to the user. The housing 602 is depicted in dotted lines and as transparent in FIG. 5 for illustrative clarity.

The device 600 includes a circuit board 606 having an edge 608 abutting the outwardly facing surface 604 of the housing 602. The capacitive touch sensor 100 that has been described is disposed at the circuit board 606, including at an edge 608 of the board 606. That is, the circuit board 606 corresponds to the substrate 102 that has been described, with the sensor 100 formed thereon. As such, the capacitive touch sensor 100 detects touch presence proximity at a corresponding location 610 of the housing 602 in front of the sensor 100. Because the touch sensor 100 includes a conductive surface 108 that in particular detects touch presence proximity at the edge 608, the device 600 does not have to include a secondary circuit board to have the sensor 100.

We claim:

1. A capacitive touch sensor comprising:
a substrate having a broad side and an edge;
a conductive surface at the edge of the substrate;
a ground layer at the substrate; and
a dielectric between the conductive surface and the ground layer,
wherein the conductive surface, the ground layer, and the dielectric form a capacitor, a capacitance of which changes responsive to proximity of touch presence at the conductive surface.

2. The capacitive touch sensor of claim 1, wherein the substrate is a printed circuit board.

3. The capacitive touch sensor of claim 1, wherein the conductive surface comprises:
a plurality of castellations at the edge of the substrate.

4. The capacitive touch sensor of claim 1, wherein the conductive surface comprises:
a plurality of conductive vias at the edge of the substrate.

5. The capacitive touch sensor of claim 1, wherein the conductive surface comprises:
a plated slot at the edge of the substrate, the slot having a long dimension parallel to the edge.

6. The capacitive touch sensor of claim 1, wherein the conductive surface comprises:
a plated electrical component at the edge of the substrate.

7. The capacitive touch sensor of claim 1, wherein the ground layer and the dielectric are disposed on the broad side of the substrate.

8. The capacitive touch sensor of claim 7, wherein the conductive surface is a first conductive surface, the capacitive touch sensor further comprising:
a second conductive surface on the broad side and conductively connected to the first conductive surface; and
an overlay over the ground layer, the dielectric, and the second conductive surface on the broad side of the substrate.

9. The capacitive touch sensor of claim 1, wherein the dielectric is a void.

10. The capacitive touch sensor of claim 1, wherein the dielectric is an insulative material.

11. The capacitive touch sensor of claim 1, wherein the conductive surface and the ground layer form plates of the capacitor.

12. The capacitive touch sensor of claim 1, wherein the broad side is a first broad side, the substrate having a second broad side opposite the first broad side, the capacitive touch sensor further comprising:
a trace at the second broad side conductively connected to the conductive surface at the edge of the substrate; and
an input/output (I/O) pin conductively connected to the trace, and to which the capacitive touch sensor is connectable to measure the capacitance.

13. The capacitive touch sensor of claim 1, further comprising:
an overlay over the edge of the substrate, including over the conductive surface at the edge of the substrate.

14. A method comprising:
measuring a capacitance of a capacitor formed by a conductive surface at an edge of a substrate, a ground layer at the substrate, and a dielectric between the conductive surface and the ground layer at the substrate;
in response to the measured capacitance changing by more than a threshold, triggering a function corresponding to actuation of a capacitive touch sensor including the capacitor,
wherein the capacitance of the capacitor changes responsive to proximity of touch presence at the conductive surface.

15. A device comprising:
a housing having an outwardly facing surface;
a circuit board disposed within the housing and having an edge abutting the outwardly facing surface of the housing; and
a capacitive touch sensor having a conductive surface at the edge of the circuit board to detect proximity of touch presence at a corresponding location on the outwardly facing surface of the housing.
